(19) United States
(12) Patent Application Publication
(10) Pub. No.: US 2009/0283040 A1
(43) Pub. Date: Nov. 19, 2009

(54) DEVICE FOR TEMPERATURE-CONTROLLED ACCOMMODATION OF A CONTAINER

(75) Inventors: Markus Reinhold, Hilden (DE); Gerhard Karl Strauch, Aachen (DE)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: AIXTRON INC., Sunnyvale, CA (US)

(21) Appl. No.: 11/722,071

(22) PCT Filed: Dec. 6, 2005
(86) PCT No.: PCT/EP2005/056519

§ 371 Date: Jun. 18, 2007

(30) Foreign Application Priority Data
Dec. 18, 2004 (DE) 10 2004 061 095.9

(51) Int. Cl. C23C 16/54

(52) U.S. Cl. 118/724

(57) ABSTRACT

The invention relates to a device for the tempered storage of a container (19) for receiving condensed materials that are transported out of the container (19) by evaporation by means of a carrier gas guided through the container. Said device comprises a housing (3) forming a chamber (25), the wall (3) of said housing being embodied in a heat-insulating manner, a passage (20, 21) in the housing wall (3) for a gas supply line or gas evacuation line (17, 18) to, or from, the container (19) arranged in the chamber (25), and a heating (16) or cooling system for tempering the chamber (25). The invention is characterised in that a gas flow producer (4) and the gas flow guiding means (5-10) guiding the gas flow produced by the gas flow producer (4) are provided in the chamber (25), the gas flow produced by the gas flow producer and formed by the gas flow guiding means (5-10) being heated by the heating system (16) and flowing alongside the container (19).

### FIELD OF THE INVENTION

The invention relates to a device for the temperature-controlled accommodation of a container for receiving condensed materials, in particular organic materials of low volatility, which are transported out of the container by evaporation by means of a carrier gas passed through the container, comprising a housing forming a chamber, the housing wall of which is formed in a heat-insulating manner, comprising a passage in the housing wall for a gas supply line or a gas discharge line to or from the container disposed in the chamber and comprising a heater or a cooling system for controlling the temperature of the chamber.

The invention additionally relates to a device for depositing layers, in particular organic layers, in which, in a heated reactor, a non-gaseous starting material stored in a source formed by a container is transported by means of a carrier gas in a gaseous state from the source to a substrate, where it is deposited on the substrate.

### BACKGROUND

A device for the temperature-controlled accommodation of a container and a device for depositing layers, in particular organic layers, is known from DE 190 48 759. The device for the temperature-controlled accommodation of a container has heatable walls, which are intended to keep the container at a temperature that is the same throughout. The gases flowing into the container are heated. The in-flowing gases flow through liquid or solid materials located in the container, in order to transport them as gas into a device in which these gaseous materials condense as a layer on a substrate.

Also known in the prior art are high-temperature ovens which keep items held in them at a constant temperature in the range from 200 to 800° C. However, the accuracy of the temperature control is only within a range of +/−3°. In the interior space, the temperature can even vary locally in a range of +/−9° C.

The Organic Vapor Phase Deposition System (OVPD technology) for the production of OLED displays, as an alternative to the known LCD displays, requires hitherto unachieved accuracy values in the control of the local and temporal temperature stability in the temperature chamber. By means of OVPD, nanometer-thick organic films can be deposited on solid substrates. The organic materials are for this evaporated in sources that are installed in high-temperature ovens. A carrier gas, such as for example nitrogen in the form of a gas mixture, is used to introduce the vapor in the source into a deposition chamber by means of a transporting line. In the deposition chamber, the organic material condenses on a cooled substrate. This layer structure that is created can be processed on the basis of just a few process steps to form an OLED display.

One of the most important aims of OVPD is to deposit thick films that are reproducible at any point in time. In physical terms, this means that, ideally, the same amount of material is converted into the gas phase at any point in time and then precipitates in the deposition chamber in films of identical thickness.

The physically determinant variable for this type of evaporation is the vapor pressure of the component located in the container, which may be liquid or solid. The greater the level of the vapor pressure at a specific temperature, the more material per unit of time can be transferred into the gas phase. Since the vapor pressure is an exponential function of the temperature, even small differences in temperature have a considerable effect on the amount of organic material that is delivered. The aim of a reproducible film thickness can consequently only be achieved by means of extreme temporal stability and local temperature homogeneity.

### SUMMARY OF THE DESCRIPTION

It is consequently an object of the invention to develop the generic device with a view to depositing organic layers at a higher level of quality.

The object is achieved by the invention specified in the claims. Each claim in principle represents an independent solution, which also contributes to achieving the object independently of other claims. However, each claim can be combined with any other claim.

Claim 1 provides first and foremost that a gas flow producer and gas flow directing means, which direct the gas flow produced by the gas flow producer, are provided in the chamber. The gas may be nitrogen or some other inert gas. The gas flow producer may be a fan. The gas flow directing means may be the walls of an internal housing. However, it is also possible for the gas flow directing means to be merely metal plates. The metal plates are preferably configured and disposed in such a way that they direct the gas flow past on the container and/or on the housing walls, so that a virtually constant and uniform temperature can be measured inside the housing. In continuous operation, the temperature stability may be +/−0.05° over a day. The temperature gradient in the oven is minimal, so that a local temperature homogeneity of +/−2° C. or better can be achieved in the entire oven region. Dependent on the heating output, the oven temperature can be set to temperatures of up to 700° C. with an accuracy of 0.1° C. The gas flow directing means produce a convective flow in the oven, directing the gas flow through the entire oven, so that all regions are at substantially the same temperature. By means of a continuous temperature measurement in the inner region and the outer region of the oven and using an electronic control algorithm, the convective flow is made to function in the outer region as a locally more active, adjustable thermal insulator. In the inner region of the internal housing is the container. The temperature of said container is also controlled by the heat emitted by the gas flow directing means. For this purpose, the surfaces of the gas flow directing means have an especially defined emitting capability. The gas flow directing means consisting of metal plates may have an appropriate surface, which is polished or rough, but preferably is also absorptive or reflective. The internal housing is preferably disposed at a spacing from the inner wall of the housing, having a spacing from the inner wall of the housing that is application-specific. The gas flow is produced by a fan, which is advantageously located on the ceiling of the housing. It may be a radial-flow fan, which sucks the gas flow out of an opening in the ceiling of the internal housing. A grill may be disposed underneath the ceiling. On the floor of the internal housing or in the region of the sides and at the top there is a heating register, which is disposed above an opening in the floor of the internal housing. Additional heating registers may be provided at the top or in the lateral ducts. The gas flowing past on the inner wall of the housing flows through this heating grill and so arrives in the internal housing, in which the container is located. The gas flow flows past on the container and leaves it again through the opening in the ceiling.

### BRIEF DESCRIPTION OF THE DRAWINGS

An exemplary embodiment of the invention is explained below on the basis of accompanying drawings, in which:

FIG. 1 shows, in schematic representation, a view through the door opening of a device for the temperature-controlled accommodation of a container, the front wall of the inner housing being omitted,

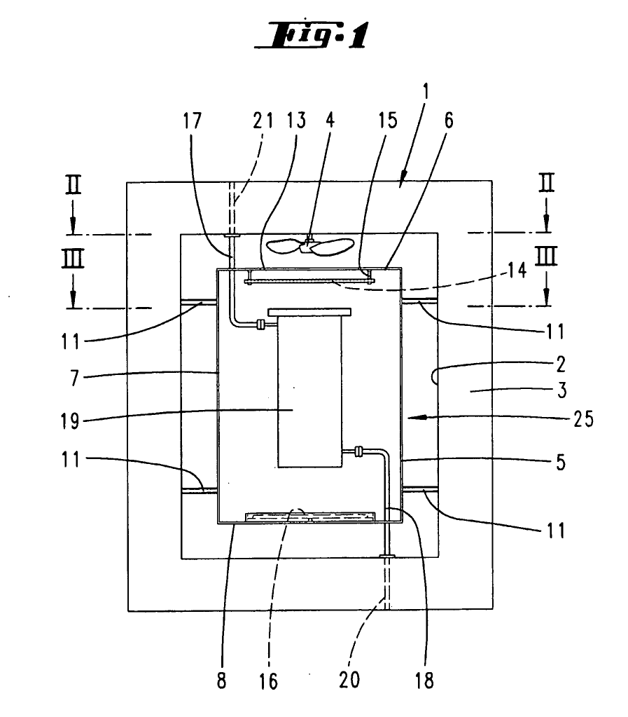

FIG. 2 shows a section along the line II-II in FIG. 1,

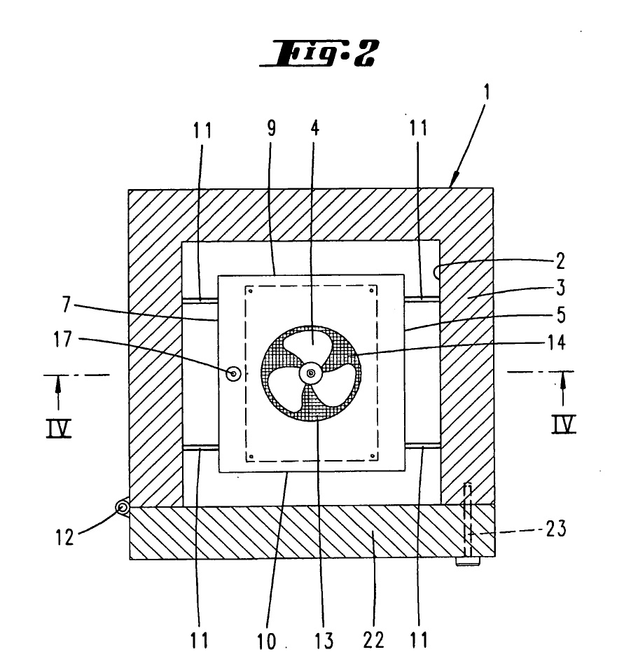

FIG. 3 shows a section along the line III-III in FIG. 1 and

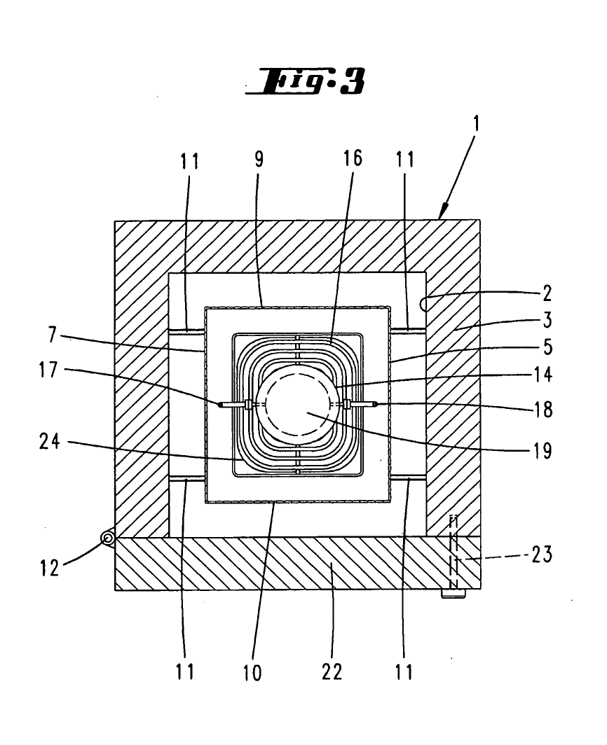

FIG. 4 shows a section along the line IV-IV in FIG. 2.

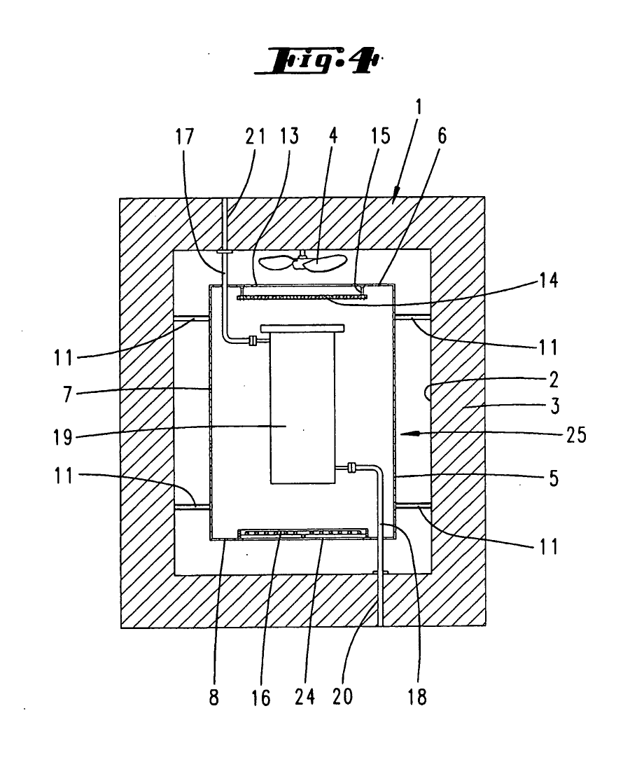

### DETAILED DESCRIPTION

The housing 1, which surrounds a chamber 25, has thermally insulating walls 3 and a door 22, which closes a door opening, is articulated on the housing by means of a hinge 12 and can be locked by means of a bolt 23, the door sealing the chamber 25 in a gas-tight and heat-insulating manner.

The upper chamber wall has a passage-opening 21 for a supply line 17, through which a carrier gas flows into a container 19, which is disposed in the chamber 25 and in which liquid or solid, powdered or granular substance to be brought into the gas form is located and, together with the carrier gas, is discharged through a discharge line 18, which discharge line 18 extends through a passage-opening 20 in the bottom region of the housing wall.

The chamber 25 is thermally insulated from the outside. Inside the rectangulate chamber 25 there is a rectangulate internal housing, which comprises side walls 5, 7, 9, 10, which are bolted or welded to one another. In addition, a ceiling panel 6 with an opening 13 and a floor panel 8 with an opening 24 are provided. This internal housing, consisting of the parts 5-10 is mounted inside the housing 1 by means of mounting members 11 in such a way that the walls 5-10 of the internal housing are at a uniform spacing from the inner wall 2 of the housing. For this purpose, the mounting members 11 extend from the inner wall 2 of the housing to the two opposing side walls 5 and 7.

Above the opening 13 in the ceiling 6 there is an electrically driven fan 4, which sucks the gas, which may be air, out of the internal housing through the opening 13. Underneath the opening 13 there is a grill 14, which is held at a spacing from the ceiling 6 of the internal housing by means of spacers 15. Above the floor 8 there is an electrical resistance heater 16. This is a heating register, which is disposed above the floor opening 24. Between the heater 16 and the fan 4, that is to say between the two openings 13 and 24, is the container 19.

If the fan 4 is switched on, it sucks gas, which may be air, through the opening 13. It distributes this sucked-in gas radially, so that it flows along between the walls of the internal housing 5-10 and the inner wall 2 of the housing. It then returns into the internal housing through the opening 24 and is heated up by the heater 16. The opposed flows on the sides of the walls 5-10, or convective mixing, has the effect of equalizing the temperature. The convective mixture thereby assists in the temperature equalization. The required temperature stability is produced. The two regions of the oven, that is to say the inner region and the outer region, are important, only one air flow being present in the inner region and in the outer region of the containers.

All features disclosed are (in themselves) pertinent to the invention. The disclosure content of the associated/attached priority documents (copy of the prior application) is also hereby incorporated in full in the disclosure of the application, including for the purpose of incorporating the features of these documents in claims of the present application.

What is claimed:

1.-20. (canceled)

21. Device for the temperature-controlled accommodation of a container (19) for receiving condensed materials, which are transported out of the container (19) by evaporation by means of a carrier gas passed through the container, comprising a housing (3) forming a chamber (25), a housing wall (3) of which is formed in a heat-insulating manner, and includes passages (20, 21) in the housing wall (3) for a gas supply line (17) or a gas discharge line (18) to or from the container (19), which is disposed in the chamber; and a heater (16) or a cooling system for controlling the temperature of the chamber (25), characterized in that a gas flow producer (4), for heating (16) or cooling, and gas flow directing means (5-10), which direct the gas flow produced by the gas flow producer (4) are provided in the chamber (25), which gas flow directing means form the walls of an internal housing receiving the container (19), on which the gas flow flows past on both sides in respectively opposed directions,

22. Device according to claim 21, characterized in that the gas flow produced by the gas flow producer and formed by the gas flow directing means (5-10) is heated by the heater (16) and flows along the container (19).

23. Device according to claim 21, characterized in that the gas flow produced by the gas flow producer (4) and directed by the gas flow directing means (5-10) flows along an inner wall (2) of the housing wall (3).

24. Device according to claim 23, characterized in that form the walls (5-10) of the internal housing and are substantially at a uniform spacing from the inner wall (2) of the housing wall (3).

25. Device according to claim 21, characterized in that heating register (16), is disposed underneath the container (19), for heating the gas flowing into the chamber (25).

26. Device according to claim 21, characterized in that the carrier gas is air or nitrogen.

27. Device according to claim 21, characterized in that the gas flow directing means (5-10) consist of metal plate.

28. Device according to claim 21, characterized in that the internal housing formed by the gas flow directing means (5-10) has through-flow openings (13, 24) in a ceiling and in a floor thereof.

29. Device according to claim 21, characterized in that surfaces of the gas flow directing means (5-10) that are facing the container (19) and an inner wall (2) of the housing wall (3) have heat radiating properties.

30. Device according to claim 21, characterized in that surfaces of the gas flow directing means (5-10) are bright, finely rough or coarsely rough.

31. Device according to claim 21, characterized in that the heater (16) is a resistance heater and is disposed above a bottom opening (24) in a wall (8), forming a floor, of the internal housing.

32. Device according to claim 21, characterized in that the gas flow producer (4) is a fan disposed on a ceiling of the housing (1), under which there is an opening (13) in a ceiling (6) of the internal housing.

33. Device according to claim 21, characterized in that the gas flow flows through the internal housing from bottom to top.

34. Device according to claim 21, characterized by mounting members (11) arranged to keep side walls of the internal housing at a spacing from an inner wall (2) of the housing wall (3).

35. Device according to claim 21, characterized in that the housing has a door (22), which is pressed by a closure, formed in particular as a bolt, against an opening of the housing and seals the chamber (25) in a gas-tight and heat-insulating manner.

36. Device for depositing layers, in particular organic layers, in which, in a heated reactor, a non-gaseous starting material stored in a source formed by a container is transported by means of a carrier gas in a gaseous state from the source to a substrate, where it is deposited on the substrate, characterized in that the source is disposed in a device according to any one of the claims 21-35.
